(19) United States
(12) Patent Application Publication
(10) Pub. No.: US 2024/0355580 A1
(43) Pub. Date: Oct. 24, 2024

(54) TRANSMISSION ELECTRON MICROSCOPE IMAGE PROCESSING APPARATUS, FACILITY SYSTEM HAVING THE SAME, AND OPERATING METHOD THEREOF

(71) Applicant: SAMSUNG ELECTRONICS CO., LTD., Suwon-si (KR)

(72) Inventors: Yeny YIM, Suwon-si (KR); Dongok KIM, Suwon-si (KR); Wonhee LEE, Suwon-si (KR); Subong SHON, Suwon-si (KR); Hansaem PARK, Suwon-si (KR); Byeongkyu CHA, Suwon-si (KR)

(21) Appl. No.: 18/471,259

(22) Filed: Sep. 20, 2023

(30) Foreign Application Priority Data
Apr. 13, 2023 (KR) 10-2023-0048648

(51) Int. Cl. H01J 37/26; G06T 5/50; G06T 7/13; G06T 7/60; G06V 20/70

(52) U.S. Cl. CPC H01J 37/26; G06T 5/50; G06T 7/13; G06T 7/60; G06V 20/70; G06T 2207/10056; G06T 2207/20104; G06T 2207/20221

(57) ABSTRACT

A method of operating a transmission electron microscope (TEM) image processing apparatus, includes acquiring a TEM image from a TEM facility, performing weak labeling of the TEM image, generating ground truth for a partially labeled TEM image using a guide model, performing segmentation using training data consisting of a pair of the TEM image and the ground truth; measuring a device core structure according to a result of the segmentation, and visualizing a measurement result according to the device core structure, and storing the same in a database.

### CROSS-REFERENCE TO RELATED APPLICATION(S)

This application claims benefit of and priority to Korean Patent Application No. 10-2023-0048648 filed on Apr. 13, 2023 in the Korean Intellectual Property Office, the disclosure of which is incorporated herein by reference in its entirety.

### BACKGROUND

The present inventive concept relates to a transmission electron microscope image processing apparatus, a facility system having the same, and an operating method thereof.

In general, a transmission electron microscope (TEM) may be a tool capable of observing a structure and properties of a material on an atomic level in a semiconductor manufacturing process. As semiconductor technology develops, it has become important to accurately measure and analyze a fine structure of a semiconductor device. However, the tasks of recognizing and measuring the structure of a semiconductor device from an image captured by the TEM may be performed manually. Accordingly, when measuring the structure of the semiconductor device, it would be desirable to reduce the burden of such manual tasks in order to improve efficiency and accuracy.

In order to automatically measure the structure of a semiconductor device, image segmentation, which may be image technology that distinguishes between an object and a background in the image, is first required. Image segmentation has recently been developed for a natural image based on usages of artificial intelligence (AI) and big data. Segmenting the structure of a semiconductor device from the TEM image may have challenges in application, such as a smaller amount of training data, an ambiguous boundary in the TEM image, or the like. In order to segment the structure in the TEM image, it is known for a user to manually generate ground truth in which a boundary between materials is marked on the TEM image, and then learn the same together with the TEM image to create an artificial intelligence model. This corresponds to strong supervision in which the user should input all correct answers to the image.

### SUMMARY

An aspect of the present inventive concept is to provide a transmission electron microscope image processing apparatus, a facility system having the same, and an operating method thereof, which reduce burden of manual work/tasks and improve efficiency and accuracy of semiconductor device measurement.

According to an aspect of the present inventive concept, a method of operating a TEM image processing apparatus includes acquiring a TEM image from a TEM facility; performing weak labeling of the TEM image to produce a partially labeled TEM image; generating ground truth for the partially labeled TEM image using a guide model; performing image segmentation using training data consisting of a pair of the TEM image and the ground truth; measuring a device core structure in the TEM image according to a result of the image segmentation; and visualizing a measurement result according to the device core structure, and storing the same in a database.

According to an aspect of the present inventive concept, a method of operating a TEM image processing apparatus includes receiving a TEM image; adding user input to the TEM image using weak labeling to produce a partially labeled TEM image; generating ground truth for the partially labeled TEM image using a guide model; determining whether the guide model satisfies a performance criterion; and generating training data when the guide model satisfies the performance criterion, wherein the ground truth or the training data includes an image for distinguishing a boundary between materials.

According to an aspect of the present inventive concept, a method of operating a TEM image processing apparatus includes collecting training data consisting of a pair of a TEM image and ground truth corresponding to the TEM image; learning a segmentation model for distinguishing a boundary between materials in an image; determining whether the segmentation model satisfies a performance criterion; performing inference for the TEM image using the segmentation model, when the segmentation model satisfies the performance criterion; measuring a device core structure according to a result of the inference; and outputting a measurement value for the device core structure.

According to an aspect of the present inventive concept, a TEM image processing apparatus includes a client device configured to receive a TEM image from a TEM facility and to add user input to the TEM image using weak labeling to produce a partially labeled TEM image; a server device configured to perform image segmentation for the partially labeled TEM image using a guide model to generate ground truth, and to perform image segmentation for a new TEM image using a segmentation model; and a database storing training data consisting of a pair of the TEM image and the ground truth.

According to an aspect of the present inventive concept, a facility includes a transmission electron microscope (TEM) facility configured to acquire a TEM image of a device core structure of a semiconductor device; and a TEM image processing apparatus configured to measure the device core structure for the TEM image using artificial intelligence, wherein the TEM image processing apparatus generates training data through user input or interaction information using weak labeling, or distinguishes a boundary between materials for the TEM image using the training data.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a view illustrating a facility system 10 for processing a TEM image according to an embodiment.

FIG. 2 is a view conceptually illustrating a process of generating ground truth of a TEM image processing apparatus 12 according to an embodiment.

FIG. 3 is a view illustrating a process of automatically measuring a device core structure of a TEM image processing apparatus 12 according to an embodiment.

FIG. 4 is a view illustrating five (5) methods of the minimal user input illustrated in FIG. 3.

FIG. 5 is a view conceptually illustrating a process of generating ground truth in a TEM image processing apparatus 12 according to an embodiment.

FIG. 6 is a view illustrating a process of adding the next user input based on an inference result and an uncertainty map in a TEM image processing apparatus 12 according to an embodiment.

FIG. 7 is a flowchart illustrating a process of generating segmentation ground truth in a TEM image processing apparatus 12 according to an embodiment.

FIG. 8A is a view illustrating a process of learning automatic generation of ground truth of a TEM image processing apparatus 12 according to an embodiment.

FIG. 8B is a view illustrating a process of learning/inferring a segmentation model of a TEM image processing apparatus 12 according to an embodiment.

FIGS. 9A and 9B are views illustrating accuracy and creation time of automatic generation of ground truth by a TEM image processing apparatus 12 according to an embodiment.

FIG. 10 is a view illustrating whether ground truth is improved according to the number of iterations in a TEM image processing apparatus 12 according to an embodiment.

FIG. 11 is a view illustrating whether ground truth is improved according to the number of iterations in a TEM image processing apparatus 12 according to another embodiment.

FIG. 12 is a view illustrating results of image segmentation model learning and inference of a TEM image processing apparatus 12 according to an embodiment.

FIG. 13 is a view illustrating a computing device 1000 for TEM image processing according to an embodiment.

FIG. 14 is a flowchart illustrating an operating method of a TEM image processing apparatus according to an embodiment.

FIG. 15 is a flowchart illustrating an operating method of a TEM image processing apparatus according to an embodiment.

### DETAILED DESCRIPTION

Hereinafter, the present inventive concept will be described clearly and in detail to the extent that a person skilled in the art may easily practice using the drawings.

Generally, a Transmission Electron Microscope (TEM) serves as a semiconductor analysis facility. Due to the miniaturization of semiconductor devices, a technique that involves destructively sampling and analyzing the core structure and specifications of each device module with a TEM image is widely used as a method for accurately measuring the structure and providing feedback to the process. In particular, TEM analysis is essential for rapid structural verification of semiconductor devices. However, conventional TEM analysis has its limitations, including a restricted amount of analysis and high measurement deviation, as it relies on manual measurements by the user. When developing a semiconductor device, it's crucial to develop technologies and devices for automatic TEM measurements to potentially accelerate the analysis of the device's core structure, which plays a key role in process verification and feedback. It is necessary to expedite analysis times and improve measurement reliability through such automatic measurements.

A TEM image processing apparatus, a facility system having the same, and an operation method thereof, according to an embodiment, may generate image annotations using Artificial Intelligence (AI). Here, image annotation refers to the process of adding supplementary information to image data. During this process, information such as descriptions, keywords, labels, categories, etc., is attributed or indicated for specific regions, objects, or features within the image. Specifically, the TEM image processing device according to the embodiments of the present invention, the facility system, and the operating method may leverage AI to automatically generate ground truth data or perform image segmentation learning, with the aim of automating the measurement of the geometric structure of semiconductor devices. Consequently, the invention has the potential to alleviate the manual workload from operators during the image annotation process, while simultaneously enhancing efficiency and accuracy. As would be understood by those of skill in the art of the present inventive concept, ground truth is information that is known to be real or true.

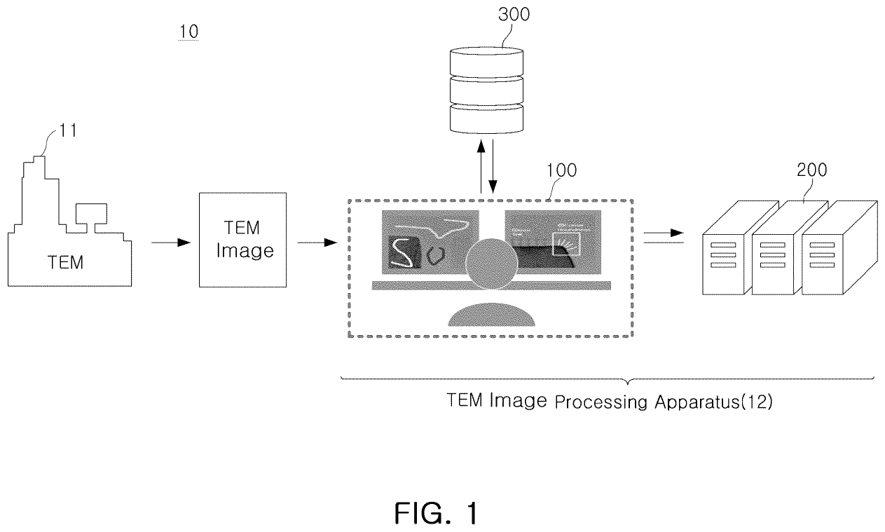

FIG. 1 is a view illustrating a facility system 10 for processing a TEM image according to an embodiment. Referring to FIG. 1, a facility system 10 may include a TEM facility 11 and a TEM image processing apparatus 12. In this case, the TEM image processing apparatus 12 may include a client device 100, a server device 200, and a database 300.

The TEM facility 11 may be implemented to acquire a TEM image of a semiconductor device. The TEM facility 11 may include a transmission electron microscope (TEM) that uses an electron to produce an image having high-resolution. The TEM facility 11 may be used to observe an internal structure and bonding of the semiconductor device.

The TEM facility 11 may include an electron light source, a vacuum system, an electronic lens, a sample holder, a detector, and an imaging analyzer. The TEM uses a filament (tungsten, lanthanum hexaboride, or the like) to emit the electron, to generate an electron beam. The electron light source may be heated to generate the electron through heat emission. The vacuum system may use a multi-stage vacuum pump to maintain a vacuum in the TEM. The vacuum may prevent the electron beam from interacting with an air molecule, to increase stability of the electron beam and quality of the image. The electronic lens may be used to modulate and focus the electron beam. The electronic lens may be a coil that creates an electromagnetic field used to change a path of the electron, as the electron beam passes therethrough. A tunable electromagnetic field may be used, to modulate the electron beam, and enlarge or reduce the image. A TEM sample should be cut to be thin such that the electron beam may pass therethrough. The sample holder may be used to stably hold the thin TEM sample. After the electron beam passes through the TEM sample, the detector may collect a signal thereof. The detector may convert the electron into light or an electrical signal to create an image. The detector may include a fragility detector, a visible light detector, or the like. The signal collected in the detector may be converted into the image by a computer system, and the image may be displayed. The image obtained in this manner may be used to analyze a structure, a defect, and a characteristic of the device.

The TEM image processing apparatus 12 may be implemented to receive the TEM image from the TEM facility 11, and automatically generate ground truth (or a label), or perform image segmentation (i.e., dividing the TEM image into multiple parts or regions that belong to the same class). The TEM image processing apparatus 12 may include the client device 100 for minimum user input, the server device 200 for automatically generating ground truth and learning/inference of a segmentation model, an interface device for data transmission between the client device 100 and the server device 200, a device for automatically measuring a device core structure, and a device for visualizing and creating a database of a measurement result.

The client device 100 may be implemented to add minimal user input to the TEM image (also referred to as weak labeling). Information input by a user may be encoded, and may be transmitted to the server device 200 through a transmission interface. After receiving and decoding the transmitted information, the server device 200 may be implemented to automatically generate ground truth through learning/inference. A generated inference result may be delivered to the client device 100. The client device 100 may visualize the inference result. The client device 100 may improve accuracy of generating ground truth by adding user input to a position of high uncertainty in an existing inference result image and then transmitting the same to the server device 200. In an embodiment, data transmission may be repeated between the client device 100 and the server device 200 until a performance condition is satisfied.

The client device 100 may encode the minimum user input into a binary image for each input having a color and a thickness. The server device 200 may decode the binary image, and may convert the same into user input information having a color and a thickness. A Y value (ground truth) of training data may be generated through the automatically generating ground truth. The training data may be collected along with an X value (the TEM image) corresponding thereto. The client device 100 may transmit the training data to the server device 200.

The server device 200 may learn the training data to update a segmentation model or evaluate performance of the segmentation model. The processes described above may be repeated by collecting additional training data until a performance criterion is satisfied. In addition, the server device 200 may automatically measure a device core structure from an image segmentation result, and may analyze a measurement result such as width/height/roughness of the structure. In addition, the server device 200 may transmit a measured result image to the client device 100, to verify whether the device core structure is made as designed and to provide feedback to the process. The client device 100 may visualize (i.e., display) the measured result image, and store a measured result value in the database 300.

As described above, the server device 200 may be implemented to update the segmentation model by learning training data and to evaluate the performance of the segmentation model.

The database 300 may be implemented to store the result value measured by the client device 100.

The facility system 10 according to an embodiment may include the TEM image processing apparatus 12 that automatically generates ground truth based on artificial intelligence, to reduce a time period for generating ground truth and minimizing user input. In addition, the facility system 10 according to an embodiment may perform image segmentation using the automatically generated ground truth, such that a segmentation result is quickly obtained and a core structure of a semiconductor device is quickly measured. As a result, faster process feedback is possible.

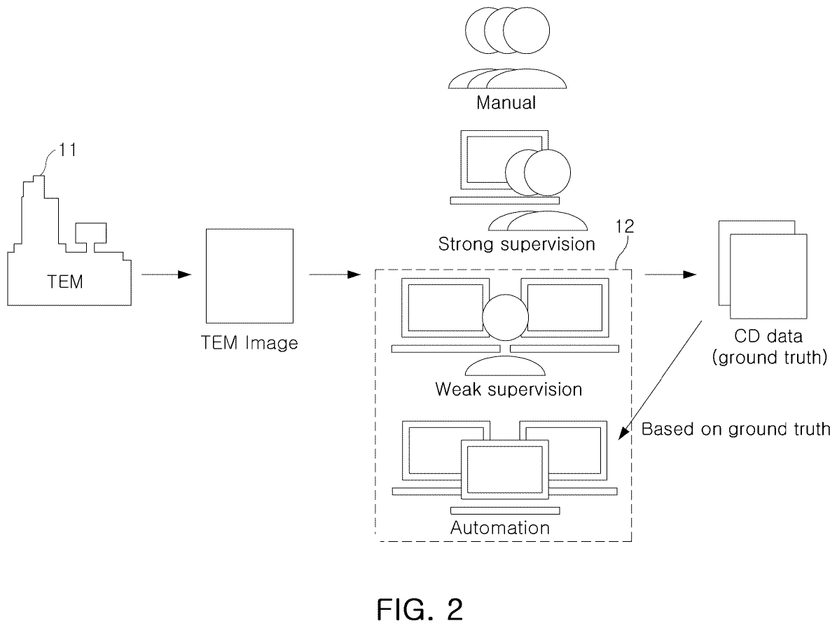

FIG. 2 is a view conceptually illustrating a process of generating ground truth of a TEM image processing apparatus 12 according to an embodiment. Referring to FIG. 2, to automatically measure a device core structure in a TEM image, ground truth for distinguishing a boundary between materials may be automatically generated with minimal user input.

A TEM image processing apparatus 12 according to an embodiment may quickly and automatically measure the device core structure in the TEM image. Existing TEM image automatic measurement techniques require a preprocessing process in which a person directly generates ground truth for model learning.

The TEM image processing apparatus 12 according to an embodiment may be implemented to automatically generate ground truth with minimum user input. The TEM image processing apparatus 12 may automatically generate ground truth indicating the boundary between materials, different from each other, in the TEM image, and may learn with the TEM image based on the ground truth, to automatically output ground truth for a new image thereafter.

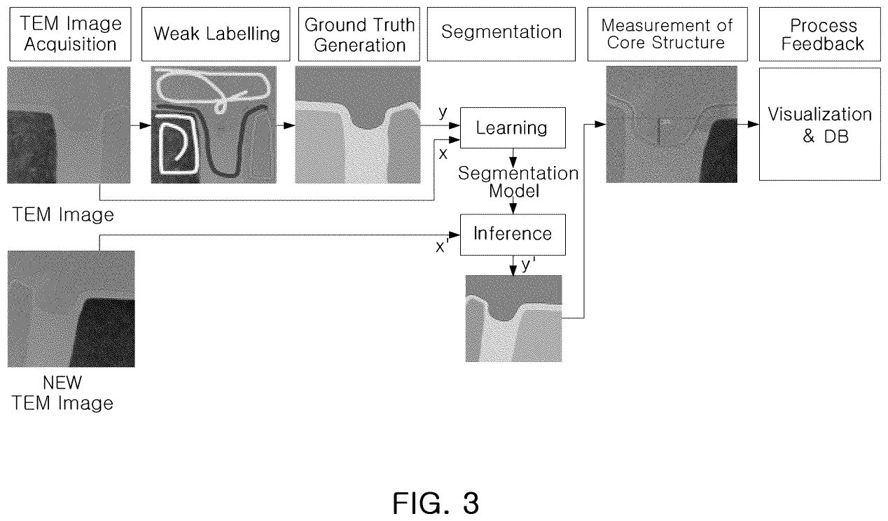

FIG. 3 is a view illustrating a process of automatically measuring a device core structure of a TEM image processing apparatus 12 according to an embodiment. Referring to FIG. 3, a TEM image may be acquired in a TEM facility 11. Thereafter, ground truth may be automatically generated with minimum user input. Hereinafter, an image segmentation model may be created by learning a pair of the acquired TEM image and the ground truth several times. Subsequently, a segmentation result in which a boundary between materials is distinguished may be output for a new TEM image newly acquired using the segmentation model. A core structure of a semiconductor device may be automatically measured using the segmentation result. Measured values therefrom may be used for process feedback and improvement.

The manual processing of general TEM image processing and ground truth generation presents limitations such as an extended time period required for ground truth generation, inaccuracies in ground truth, deviations in ground truth, and more. For instance, it may take 30 to 60 minutes to generate ground truth per image sheet. Additionally, an individual may generate ground truth corresponding to all pixels in the image. As it is necessary to generate at least one hundred (100) pieces of ground truth for learning-based segmentation, a pre-processing time of at least fifty (50) hours is required, limiting the ability to perform fast process feedback. Furthermore, inaccuracies and deviations may occur between users when generating ground truth. TEM analysis obtains an image by making a sample into a thin specimen for precise structural measurement (<0.1 nm precision) and capturing it with a microscope. As the production of the sample and video recording are performed manually, video recording conditions such as sample thickness and lighting can change. Consequently, deviations in image quality can be significant. Often, the boundary between materials in a TEM image is unclear due to factors like grain size and texture. Thus, it can be challenging and inaccurate for users to precisely classify the boundary during analysis. Additionally, deviations may occur between users.

A TEM image processing apparatus 12 according to an embodiment may automatically generate ground truth with minimum user input, to give an effect such as reducing a segmentation time period (≤10% compared to the previous one), reducing user input (the number of inputs per material: 100 times≤5 times), maintaining and improving accuracy (≥98%), or the like. In addition, a TEM image processing apparatus 12 according to an embodiment may be applied to all TEM facilities and analysis systems, acquiring a TEM image, to automatically measure a device core structure, and to increase a process feedback speed through visualization and databasing of measurement results.

A TEM image processing apparatus 12 according to an embodiment may include an algorithm for automatically generating ground truth with minimum user input, and a segmentation model learning and inference algorithm for distinguishing a boundary between materials.

A TEM image processing apparatus 12 according to an embodiment may be implemented with a user interface and an algorithm for automatically generating ground truth with minimum user input. Minimum user input according to an embodiment may be used to automatically generate more accurate ground truth in an AI-based model. In this case, the minimum user input means giving correct answer information for each material to a region through simple input such as a point, a line, a curve, or the like. Accuracy of ground truth may be improved by adding user input to an uncertain portion or an inaccurate portion of an existing prediction result.

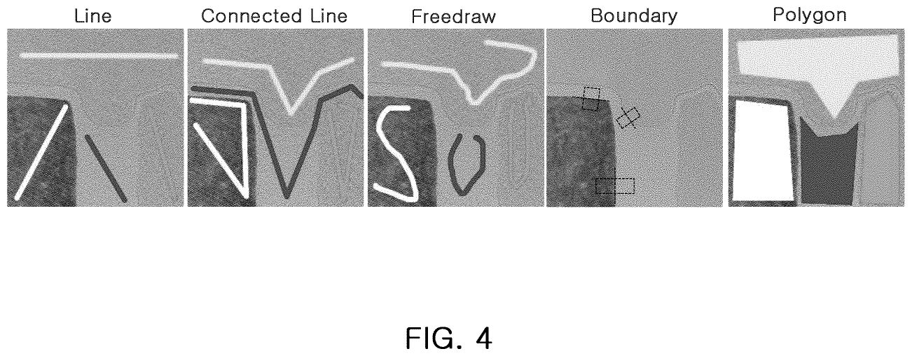

FIG. 4 is a drawing that exemplifies the five methods of minimum user input depicted in FIG. 3. Referring to FIG. 4, the minimum user input can include five methods: line, connected line, freedraw, boundary, and polygon. Each user input has a color and thickness. The line may be drawn by clicking two points representing the start and end. The connected line composed of N lines may be drawn by sequentially clicking N+1 points. The Freedraw allows users to freely move strokes on the image, like drawing with a brush on a canvas through mouse dragging. The boundary may be entered by drawing a line perpendicular to the boundary between materials. The color of the start and end points may be determined by the color at each point in the existing inferred result image. The polygon may be drawn by sequentially clicking N points in the shape of an N-sided polygon, and the interior is filled with color. A color table registering color information for each material may be created. By selecting a color from the color table, each user input may be assigned a color.

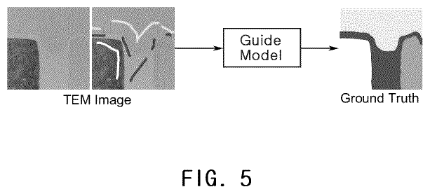

FIG. 5 is a view conceptually illustrating a process of generating ground truth in a TEM image processing apparatus 12 according to an embodiment. Referring to FIG. 5, a guide model may receive a TEM image, and may output ground truth. The guide model may be an artificial intelligence model or a machine learning model, which may be used in intermediate stages of data generation, labeling, pre-processing, and quality improvement.

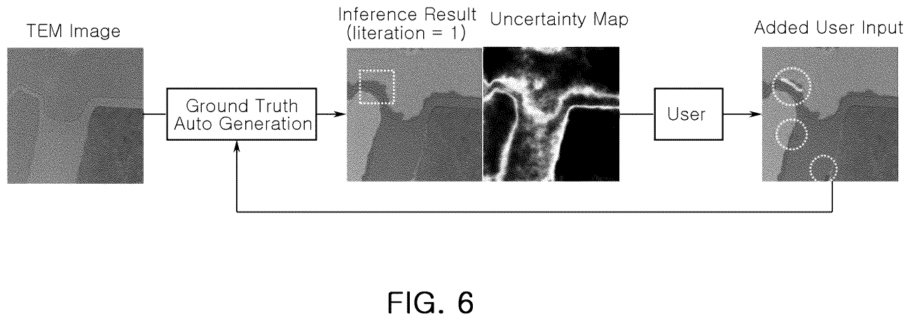

FIG. 6 is a view illustrating a process of adding the next user input based on an inference result and an uncertainty map in a TEM image processing apparatus 12 according to an embodiment. Referring to FIG. 6, an inference result of ground truth automatically generated based on minimum user input may be translucently overlaid on a TEM image, and may be displayed on a screen. The inference result can be seen by comparing with a boundary between materials of the TEM image itself. In an embodiment, transparency may be adjusted with a slider in a range of 0 to 100. User input and an inference result may be determined whether to display or hide on the screen through a toggle button. Each pixel of the image may have an inference result and an uncertainty map of a material corresponding thereto. In this case, uncertainty may have a range of 0 to 255 for each pixel. For example, the uncertainty may have a value close to 255, and may then gradually decrease to have a value close to 0, as learning repeatedly progresses through an algorithm. An image for the uncertainty may be displayed on the screen.

To give position information requiring additional user input in the image to a user, the most uncertain position may be displayed as a quadrangle as illustrated in FIG. 6. The quadrangle marked in the most uncertain region and the uncertainty map may be used for active learning. In this case, the active learning may obtain an inference result having the same accuracy even with the minimal user input, in a process of repeating inference and user input for automatically generating ground truth.

A system for automatically generating ground truth, according to an embodiment, may include a segmentation model and a guide model. The segmentation model may generate a segmentation result from the TEM image, and may transmit the same to an automated measurement system. The guide model may provide inference result information (segmentation information, an uncertainty map) such that the user may easily, accurately, and quickly add user input. The guide model may be a temporary model that helps generate ground truth. It may be continuously updated while receiving user input, and may be deleted after finally generating ground truth. Ground truth may be generated by repeating for at least one image for which ground truth is created. As iterations progress, uncertainty may decrease, and the number of user input required may drastically decrease.

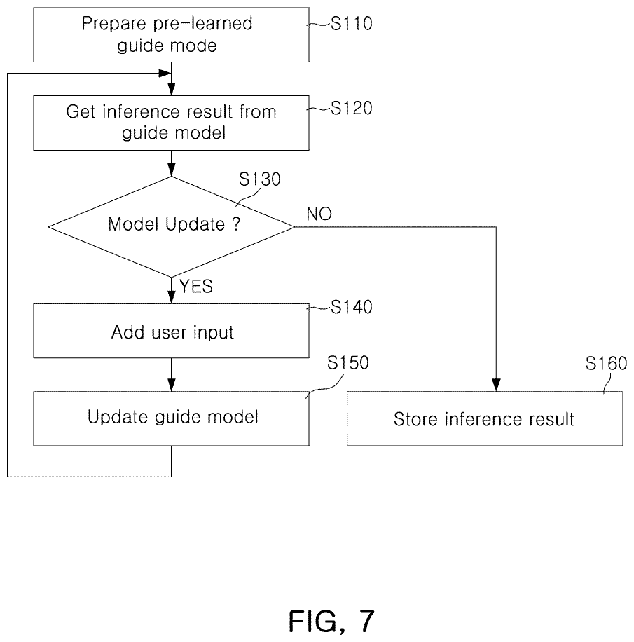

FIG. 7 is a flowchart illustrating a process of generating segmentation ground truth in a TEM image processing apparatus 12 according to an embodiment. Referring to FIG. 7, a process of generating segmentation ground truth in a TEM image processing apparatus 12 may proceed as follows.

A pre-learned guide model may be prepared (S110). Any model that receives a TEM image and outputs segmentation may be used as the pre-learned guide model. As the pre-learned guide model, what is learned with a dataset among the following datasets may be used, depending on a situation. First, when a general natural image (a public dataset) is first applied, a model pre-learned with a disclosed general natural image, or a disclosed pre-learning model may be used. Second, when a TEM image having a different structure has ever created a segmentation model from an image having a different material or a different structure, a model pre-learned by the TEM image may be used. Third, when a segmentation model has been created using a pattern corresponding thereto from a TEM image having a target structure, and performance of this segmentation model is required to be improved, a guide model pre-learned by copying a previously generated model may be used.

Afterwards, the guide model may output an inference result (S120). The guide model may output a segmentation result and an uncertainty map from the TEM image. A person may look at the segmentation result and the uncertainty map to determine where additional user input is needed. It may be helpful in specifying a location and a color of user input with an image created by overlaying the segmentation result and the TEM image in a semi-transparent manner.

It may be determined whether an update of the guide model is required (S130). When the update of the guide model is required, user input may be added (S140). The segmentation result of the guide model and the TEM image may be compared by a user to add the five types of user input to a portion considered to be different or a portion having a high value of the uncertainty, as illustrated in FIG. 4. When positions of the user inputs overlap, what is input later in the learning process of the guide model may be used with a relatively high weight. Thereafter, the guide model may be updated (S150). The guide model may be updated in a direction in which accuracy of the added user input increases and uncertainty decreases. Since a goal is to output only a result of a current image well, overfitting may be performed on the current image without data augmentation (a technique of augmenting the number by applying various transformations to an original to increase an amount of data). In this case, a loss function may use a cross-entropy function having different weights for each position of the image.

When the guide model does not need to be updated, the inference result may be stored as a correct answer (S160). When the user checks the inference result and there is no place to modify the same, a current inference result may be stored as ground truth.

A correct answer generation algorithm according to an embodiment may overfit a guide model that does not secure generality in all TEM image domains, and generates ground truth for a localized image currently being processed. In addition, a correct answer generation algorithm according to an embodiment may actively participate in a repetitive learning process by the user, to select optimal data that obtains maximum performance with minimum user input, and may mark the uncertainty map and the most uncertain region to an image, to help a user selection.

Segmentation learning is possible with a small number of images using a localized and balanced active learning algorithm according to an embodiment, and improved effects in time/cost/distribution/consistency may be obtained.

A total loss function used for learning the guide model may be calculated as a sum of loss functions of all positions, and a loss function of a j^{th} pixel may be calculated by multiplying a cross-entropy value of a position by a weight and using the following equation:

$$Loss = {\sum }_{j} {Loss}_{j} \qquad [ Equation 1 ]$$

$${Loss}_{j} = {w}_{j} {CE}_{j} = - {w}_{j} {\sum }_{i = 0}^{n - 1} {y}_{ij} log ( {p}_{ij} )$$

$$j : pixel index$$

$$w : weight$$

$$n : number of classes$$

$$p : prediction output$$

In this case, a weight of the j^{th} pixel, wⱼ, may be calculated to satisfy the following six (6) conditions by considering two pieces of information. In this case, the two pieces of information may be a piece of information on whether a position is minimum user input (foreground) or other positions (background), and a piece of information on previous inference results (a segmentation result, accuracy, and an uncertainty map). In this case, the six (6) conditions may include a condition that is inversely proportional to accuracy in the foreground, a condition that equalizes a sum per class and not biased to one class, a condition that limits a range of uncertainty values in the background to restrict influence of too large or too small, a condition that is inversely proportional to uncertainty in the background and a low weight is given to the uncertain region, a condition that a ratio of a sum of weights of the background and the foreground is manually adjusted, and a condition a weight always has a positive (+) value and a sum of weights of an entire image is 1. To satisfy these conditions, the weight may be calculated by the following equation:

$$Accuracy at i - th labeling {f}_{ace}^{i} = \frac{{\sum }_{f}^{foreground} δ \text{?}}{{\sum }_{f}^{foreground} 1} \qquad [ Equation 2 ]$$

$$Weight at a foreground point f for a given \\ \\ \\ weak label class {c}_{f}^{w} {w}_{f}^{i} ( c \text{?} ) = \frac{( 1 - facc ) δ \text{?}}{{\sum }_{f}^{foreground} ( 1 - {f}_{acc} ) δ \text{?}}$$

$$Total weight of class {c}_{f}^{w} in foreground {w}_{f}^{c} = {\sum }_{i} {w}_{f}^{i} ( c )$$

$$Total weight of class {c}_{f}^{w} in background w \text{?} = max ( \{ 0 , \frac{2}{{\sum }_{c} 1} - {w}_{f}^{c} \} )$$

$$Weight for each weak label at i - th labeling {W}_{f}^{i} = T [ {k}_{f} max ( \{ {w}_{f}^{i} ( {c}_{f}^{i , i} ) , c ∈ C \} ) ]$$

$$Weight for each background predicted as c class {W}_{b}^{c} = T [ {k}_{b} {w}_{b}^{c} max ( \{ 0 , min ( \{ 1 , 1 - \frac{Ω}{max Ω} \} ) \} ) ] \text{?}$$

$$i : class index$$

$$c : segmentation class$$

$$f : foreground$$

$$b : background$$

$$p : prediction$$

$$l : weak label$$

$$w , W : weights$$

$$T : transfer map$$

$$Ω : entropy$$

$$k : weighting parameter$$

$$\text{?} \text{indicates text missing or illegible when filed}$$

An active learning algorithm discloses a method for selecting optimal data, e.g., whether to achieve maximum performance with minimum user input, when a person's correct answer is requested, in a situation not having ground truth. According to an embodiment, a time period for a user to select a minimum user input region may be reduced by displaying an uncertainty map and the most uncertain region on an image. The uncertainty map may be calculated by normalizing entropy of an inference result to have a value between 0 and 255, as illustrated in the equation below:

$${Uncertainty}_{j} = \frac{{H}_{j}^{n}}{upper\_bound ( {H}^{n} )} \times 255 = \frac{- {\sum }_{i = 0}^{n - 1} {p}_{ij} log {p}_{ij}}{log n} \times 255$$

$$j : pixel index$$

$$i : class index$$

$$n : number of classes$$

$$H : entropy$$

In addition, an algorithm of learning and inferring a segmentation model for distinguishing a boundary between materials may be used. Training data consists of a pair of an image (X) acquired from a TEM facility and ground truth (Y) automatically generated by a guide model. The segmentation model may be updated whenever at least one new piece of training data may be generated. Since the segmentation model may be used as a pre-learned model for the guide model, it may be updated frequently to improve initial performance of the guide model.

The segmentation model, unlike the guide model, should be learned to have high generality. Therefore, when the segmentation model is learned, the input image may be changed in various manners by data augmentation, and when a dataset is divided into a learning set and an evaluation set and performance of the evaluation set deteriorates, the learning may be stopped to prevent the model from overfitting. The segmentation model may be learned by following the process below. A model and a pre-learned weight may be prepared. The data augmentation may be used to perform a data pre-processing operation. Model learning may be performed using a cross-entropy loss function. Hyperparameters of the model and optimizer may be selected to increase the performance of the evaluation set. After the evaluation set is included in the learning set, learning may be performed with the selected hyperparameter.

Also, a TEM image processing apparatus 12 may perform model performance evaluation. The TEM image processing apparatus 12 may compare a segmentation result and ground truth automatically generated by the guide model, to evaluate performance of a model for the evaluation set. As an indicator for confirming the performance, a mean-intersection-over-union (mIoU), a mean-accuracy-of-each-class (mAcc), and an all-pixel-accuracy (aAcc) may be used. In this case, the mIoU may be an average obtained after calculating an area-of-overlap/area-of-union (IoU) in each class, and the IoU may be calculated by dividing an area in which a correct answer and an output match by a total area of a correct answer region and an output region. Accuracy may be calculated by dividing the correct answer region by the entire region. The mAcc may be an average obtained after calculating for each class, and the aAcc may be calculated by extending to all classes. Since viewpoints of each of the indicators are slightly different, performance thereof may be compared by checking the three (3) indicators at the same time.

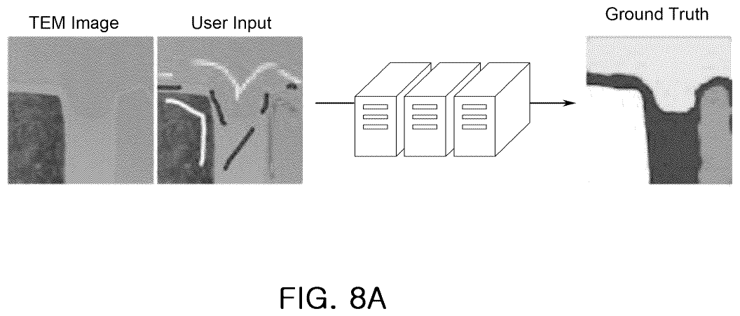

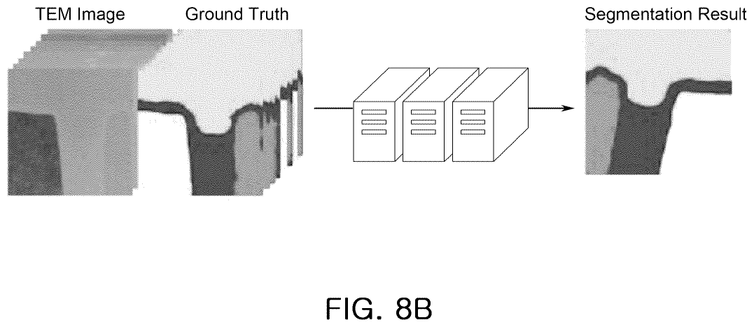

FIG. 8A is a view illustrating a process of learning automatic generation of ground truth of a TEM image processing apparatus 12 according to an embodiment. A user may add minimal user input to a TEM image in a client device 100. Information input by the user may be encoded, and may be transmitted to a server device 200 through a transmission interface. The server device 200 may decode the transmitted information, and may automatically generate ground truth by learning and inference. In this case, a generated inference result may be transferred to the client device 100, and the result may be visualized. Accuracy of generating the ground truth may be improved by adding user input to a position of high uncertainty in an existing inference result image in the client device 100 and then transmitting the same to the server device 200. Data transmission may be repeated between the client device 100 and the server device 200 until performance conditions are satisfied. For transmission, the minimum user input in the client device 100 may be encoded to have a binary image for each input having a color and a thickness. The server device 200 may decode this binary image, and convert the same into user input information having a color and a thickness.

FIG. 8B is a view illustrating a process of learning/inferring a segmentation model of a TEM image processing apparatus 12 according to an embodiment. Referring to FIG. 8B, a Y value (ground truth) of training data may be generated by an operation of automatically generating the ground truth. The training data may be collected along with an X value (a TEM image) corresponding thereto. The training data may be transmitted to a server device 200. The server device 200 may learn the training data to update a segmentation model, and may evaluate performance of the model. The processes described above may be repeated by collecting additional training data until a performance criterion is satisfied.

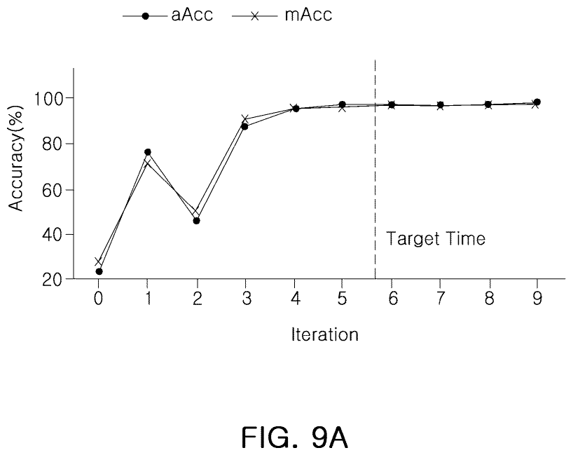

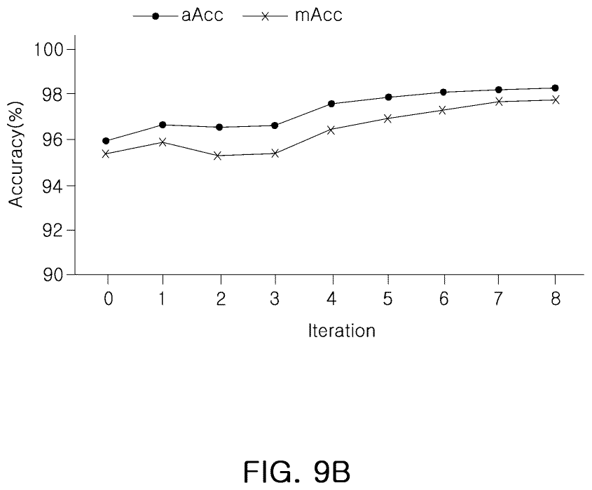

FIGS. 9A and 9B are views illustrating accuracy and creation time of automatic generation of ground truth by a TEM image processing apparatus 12 according to an embodiment. FIG. 9A is a result of pre-learning with a normal natural image (a pre-learning model #1), and FIG. 9B is a result of pre-learning with a TEM image (a pre-learning model #2) having a target structure.

According to an embodiment, accuracy and generation time of automatically generated ground truth are illustrated. The accuracy is illustrated as being improved by repeating a process of adding minimal user input and a process of automatically generating ground truth (based on pre-learning models #1 and #2). As illustrated in FIG. 9A, in using a model pre-learned with general natural images, accuracy exceeding 95%, 96%, and 98% were obtained, when the number of iterations was 4, 5, and 9, respectively. As illustrated in FIG. 9B, in using a model pre-learned with a sheet of TEM image having the same device target structure, 96% accuracy is illustrated from an initial inference result. Ground truth with 98.3% accuracy may be automatically generated at 8 iterations.

FIG. 9A takes a generation time period of 2 minutes and 49 seconds for 5 iterations, and FIG. 9B takes a generation time period of 1 minute and 57 seconds for 8 iterations. Ground truth that satisfies 95% and 98% or higher accuracy, respectively, within 3 minutes, which may be the target time, may be generated. When ground truth is manually generated, it may take 30 to 60 minutes per image, depending on a target structure.

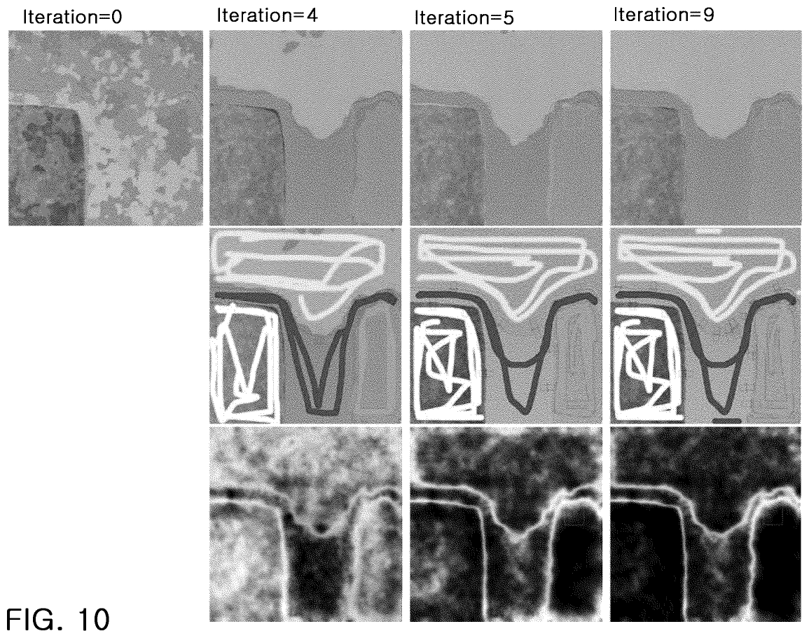

FIG. 10 is a view illustrating whether ground truth is improved according to the number of iterations in a TEM image processing apparatus 12 according to an embodiment. Referring to FIG. 10, each row illustrates a qualitative performance result when using a pre-learning model #1. It can be seen that when the number of iterations is 5, a brightness value of an uncertainty map is significantly lowered, as compared to 4 times. It can be confirmed that when the number of iterations is 9, accuracy is improved in a boundary region between images, a boundary region between materials, or the like.

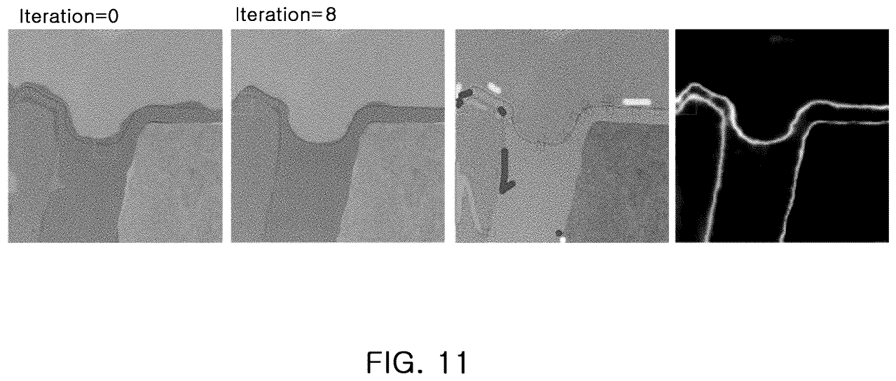

FIG. 11 is a view illustrating whether ground truth is improved according to the number of iterations in a TEM image processing apparatus 12 according to another embodiment. FIG. 11 illustrates a qualitative evaluation result when using a model #2 pre-learned with a TEM image. Inference results of 0 iteration/8^{th} iteration, added user input, and an uncertainty map are illustrated. As compared to that of FIG. 10, a region for each material may be relatively accurately distinguished from an initial inference result (0 iteration). It can be seen that a relatively small number of user input may be required to achieve over 98% accuracy. In addition, the uncertainty map at 8^{th} iteration illustrates a value close to 0, except for a boundary between materials. These experimental results illustrate that the present inventive concept may automatically generate ground truth with an accuracy of 98% or more within 10% of a time period of the prior art by adding minimum user input. It illustrates that performance improves both in terms of execution time and accuracy when using a model pre-learned with the TEM image.

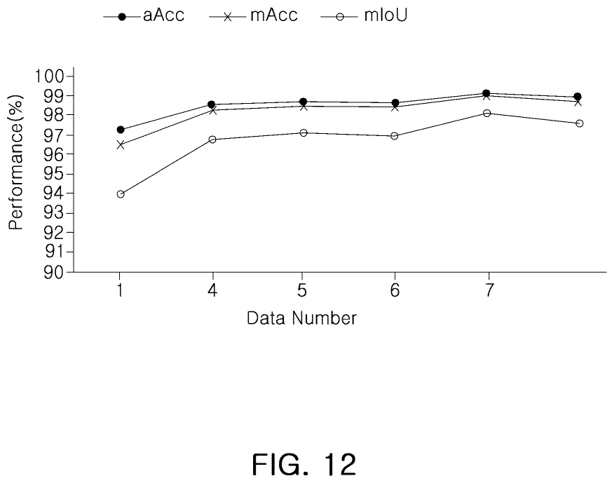

FIG. 12 is a view illustrating results of image segmentation model learning and inference of a TEM image processing apparatus 12 according to an embodiment. Referring to FIG. 12, quantitative evaluation results for image segmentation model learning and inference according to the number of training data are illustrated. It can be seen that accuracy increases, as the number of training data increases. It can be seen that when learning 7 sheets of TEM images and ground truth corresponding thereto, it is possible to secure the same level, as that in 20 times learning of the existing technique.

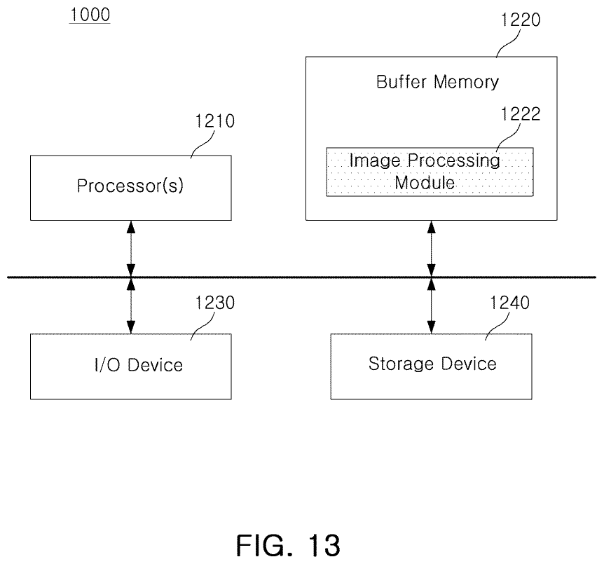

FIG. 13 is a view illustrating a computing device 1000 for TEM image processing according to an embodiment. Referring to FIG. 13, a computing device 1000 may include at least one processor 1210, a memory device 1220, an input/output device 1230, and a storage device 1240, connected to a system bus. The computing device 1000 may be included in a client device 100 or a server device 200, as illustrated in FIG. 1.

The computing device 1000 may be provided as a dedicated device for measuring a core structure of a semiconductor device. The computing device 1000 may include various measurement simulation programs. Through the system bus, the processor 1210, the memory device 1220, the input/output device 1230, and the storage device 1240 may be electrically connected to each other, and may exchange data with each other. A configuration of the system bus 1001 is not limited to the above description, and may further include mediation means for efficient management.

The at least one processor 1210 may be implemented to control overall operations of the computing device 1000. The processor 1210 may be implemented to execute at least one instruction. For example, the processor 1210 may be implemented to execute software (an application program, an operating system, and device drivers) to be executed in the computing device 1000. The processor 1210 may execute an operating system loaded into the memory device 1220. The processor 1210 may execute various application programs to be driven based on the operating system. For example, the processor 1210 may drive a TEM image processing module 1222 read from the memory device 1220. In an embodiment, the processor 1210 may be a central processing unit (CPU), a graphics processing unit (GPU), a microprocessor, an application processor (AP), or any processing unit similar thereto.

The memory device 1220 may be implemented to store the at least one instruction. For example, the memory device 1220 may be loaded with the operating system or the application programs. When the computing device 1000 boots, an OS image stored in the storage device 1240 may be loaded into the memory device 1220, based on a booting sequence. All input/output operations of the computing device 1000 may be supported by the operating system. Similarly, the application programs selected by a user or for providing basic services may be loaded into the memory device 1220. In particular, the image processing module 1222 for processing a TEM image may be loaded into the memory device 1220 from the storage device 1240. As described above with reference to FIGS. 1 to 12, the image processing module 1222 may include an algorithm for automatically generating ground truth or an image segmentation algorithm.

In addition, the memory device 1220 may be a volatile memory such as a dynamic random access memory (DRAM), a static random access memory (SRAM), or the like, or may be a non-volatile memory such as a flash memory, a phase-change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like.

The input/output device 1230 may be implemented to control user input and user output from a user interface device. For example, the input/output device 1230 may receive information from the user using an input means such as a keyboard, a keypad, a mouse, a touch screen, or the like.

The storage device 1240 may be provided as a storage medium of the computing device 1000. The storage device 1240 may store application programs, an OS image, and various data. The storage device 1240 may be provided as a mass storage device such as a memory card (an MMC, an eMMC, an SD, a Micro SD, or the like), a hard disk drive (HDD), a solid state drive (SSD), a universal flash storage (UFS), or the like.

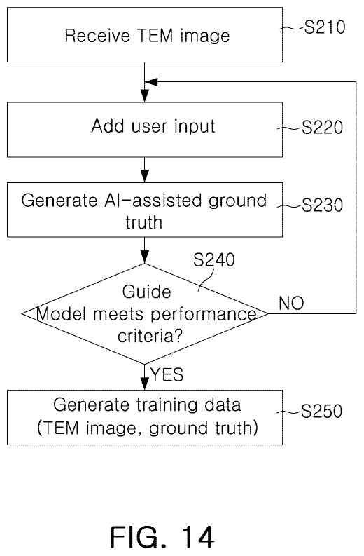

FIG. 14 is a flowchart illustrating an operating method of a TEM image processing apparatus according to an embodiment. Referring to FIGS. 1 to 14, a method of generating training data of a TEM image processing apparatus 12 may proceed as follows.

A computing device 1000 may receive a TEM image (S210). The computing device 1000 may perform minimum user input (S220). For example, weak labeling may be performed on the TEM image. Afterwards, the computing device 1000 may generate ground truth based on artificial intelligence (S230). Afterwards, the computing device 1000 may determine whether a learning model satisfies a performance criterion (S240). When the learning model satisfies the performance criterion, the computing device 1000 may generate training data (S250). In this case, the training data may include a TEM image and ground truth corresponding thereto. When the learning model does not satisfy the performance criterion, additional user input (S220) may be entered. For example, a process of automatically generating the user input and the AI-based ground truth may be repeated, until the model satisfies the performance criterion.

In an embodiment, a process of automatically generating ground truth may apply a pre-learned model to a TEM image to obtain an initial inference result, may add minimum user input to generate more accurate ground truth, may learn a model for automatically generating ground truth using the TEM image, the user input, and an existing inference result, may perform performance evaluation of a segmentation model, and may perform a new inference with the learned model to obtain a resulting image. By repeating the above operations, an inference result image (generated ground truth) may be more accurate according to the user input. As iteration progresses, the number of required user inputs may gradually decrease.

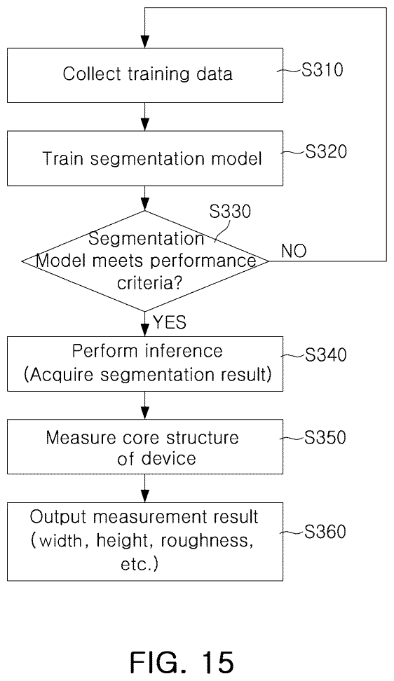

FIG. 15 is a view illustrating an operating method of a TEM image processing apparatus according to an embodiment. Referring to FIGS. 1 to 15, a method of performing image segmentation of a TEM image processing apparatus 12 may proceed as follows.

As mentioned above, a computing device 1000 may generate ground truth Y corresponding to a TEM image X by a process of automatically generating the ground truth. The computing device 1000 may collect several sheets of (X, Y) training data (S310). Afterwards, the computing device 1000 may learn a segmentation model for distinguishing a boundary between materials in an image (S320). Afterwards, the computing device 1000 may evaluate performance of an image segmentation model to determine whether a performance criterion is satisfied (S330). When the performance of the image segmentation model does not satisfy the performance criterion, collected training data (S310) may be entered. For example, a process of collecting the training data and a process of learning the model may be repeated until the performance criterion such as accuracy or the like is satisfied. When the image segmentation model satisfies the performance criterion, the computing device 1000 may perform inference to obtain a segmentation result image (S340). The computing device 1000 may automatically measure a device core structure according to an inference result (S350). Afterwards, the computing device 1000 may output the measured device core structure (width/height/roughness) to a user's display device (S360).

In an embodiment, the learning the segmentation model may include encoding user input or interaction information for a TEM image in a client device 100 (see FIG. 1); decoding the user input or the interaction information encoded in a server device 200 (see FIG. 1); and using the decoded user input or the decoded interaction data by the server device 200 to update a segmentation model. In this case, inference on the TEM image may be performed using the updated segmentation model.

In an embodiment, the device core structure may include a measurement value for a width, a measurement value for a height, and a measurement value for a roughness. In this case, the measured values may be stored in a database 300 (see FIG. 1).

An embodiment may be interlocked with and applied to all TEM facilities and an analysis system. In particular, as next-generation devices are miniaturized and demand for destructive analysis increases for accurate measurement, automatic measurement of the device core structure and acceleration of process feedback may greatly contribute to acceleration of analysis amount and analysis time and improvement of measurement reliability. In particular, in a conventional technology, a user manually generates ground truth for image segmentation, resulting in pre-processing time for collecting training data. Even with minimal user input, automatic generation of ground truth is expected to enable measurement of the device core structure and process feedback with minimal human intervention and labor.

The device described above may be implemented with a hardware component, a software component, and/or a combination of the hardware component and the software component. For example, a device and a component, described in an embodiment, may be implemented using at least one general purpose computer or at least one special purpose computer, such as a processor, a controller, an arithmetic logic unit (ALU), a digital signal processor, a microcomputer, a field programmable gate array (FPGA), a programmable logic unit (PLU), a microprocessor, or any other device capable of executing and responding to an instruction. A processing apparatus may run an operating system and at least one software application running on the operating system. The processing apparatus may also access, store, manipulate, process, and generate data in response to execution of software. For convenience of understanding, there may be cases in which one processing apparatus is used, but those skilled in the art will understand that the processing apparatus includes a plurality of processing elements or a plurality of types of processing elements. For example, the processing apparatus may include a plurality of processors, or a processor and a controller. A different processing configuration is also possible, such as a parallel processor.

The software may include a computer program, a code, an instruction, or a combination of one or more of the foregoing, which may configure a processing apparatus to operate as desired, or may command independently or collectively the processing apparatus. The software and/or data may be embodied in any type of machine, component, physical device, virtual equipment, computer storage medium or device, intended to be interpreted by or to provide the instruction or the data to the processing apparatus. The software may be distributed on a networked computer system, and may be stored or executed in a distributed manner. The software and the data may be stored on at least one computer readable medium.

The invention includes a method for automatically generating image segmentation ground truth data through user input or interaction and Artificial Intelligence (AI) for a given image. In some embodiments, the user may input a line layer or mask into the given image, allowing image segmentation ground truth data to be automatically generated through AI. In other embodiments, the user may input a freeform layer or mask into the given image, which allows AI to automatically generate image segmentation ground truth data. In yet other embodiments, the user may input a boundary layer or mask into the given image, which allows AI to automatically generate image segmentation ground truth data. In certain embodiments, the user may input a polygon layer or mask into the given image, enabling AI to automatically generate image segmentation ground truth data. In some embodiments, the user may input a combination of line, freeform, boundary, or polygon layers or masks into the given image, allowing AI to automatically generate image segmentation ground truth data. In some embodiments, the user input or interaction information for the given image may be encoded and transmitted.

An embodiment discloses a method for improving a model automatically generating image segmentation ground truth data through user input or interaction information for a given image, and artificial intelligence. In an embodiment, the model for automatically generating the image segmentation ground truth data through the user input or the interaction information for the given image, and the artificial intelligence may be automatically improved. In an embodiment, the model for automatically generating the image segmentation ground truth data through the user input or the interaction information for the given image, and the artificial intelligence may be improved, and then the model may be stored in a server. In an embodiment, the model for automatically generating the image segmentation ground truth data through the user input or the interaction information for the given image, and the artificial intelligence may be loaded from the server to a client.

An embodiment discloses a method for automatically generating image segmentation ground truth data through artificial intelligence that has learned with an image similar to a given image, and segmentation ground truth of the image. In an embodiment, image segmentation ground truth data of a given semiconductor device TEM image may be automatically generated. In an embodiment, a boundary between materials may be automatically distinguished from the ground truth of the given semiconductor device TEM image.

An embodiment discloses a method for measuring a device core structure (width, height, roughness) from a semiconductor device TEM image in which a boundary between materials is distinguished. In an embodiment, the device core structure may be automatically measured from the semiconductor device TEM image in which a boundary between materials is distinguished.

An embodiment discloses a method for storing a result of automatically measuring a device core structure from a semiconductor device TEM image in which a boundary between materials is distinguished. In an embodiment, the device core structure measured from the semiconductor device TEM image in which a boundary between materials is distinguished may be automatically stored.

An embodiment discloses an apparatus and a system for automatically generating image segmentation ground truth data through user input or interaction information for a given image, and artificial intelligence. In an embodiment, a user may input a linear layer or mask to the given image, to automatically generate the image segmentation ground truth data through the artificial intelligence. In an embodiment, the image segmentation ground truth data may be automatically generated through the artificial intelligence, when the user inputs a freedraw layer or mask to the given image. In an embodiment, the image segmentation ground truth data may be automatically generated through the artificial intelligence, when the user inputs a boundary layer or mask to the given image. In an embodiment, the user may input a polygonal layer or mask to the given image, to automatically generate the image segmentation ground truth data through the artificial intelligence. In an embodiment, the image segmentation ground truth data may be automatically generated through the artificial intelligence by the user inputting a combination of a linear, freedraw, boundary, polygonal layer or mask to the given image. In an embodiment, an interface device and a system for encoding and transmitting the user input or the interaction data for the given image may be further included.

An embodiment discloses an apparatus and a system for improving a model automatically generating image segmentation ground truth data through user input or interaction information for a given image, and artificial intelligence. In an embodiment, the model for automatically generating the image segmentation ground truth data through the user input or the interaction information for the given image, and the artificial intelligence may be automatically improved. In an embodiment, the model for automatically generating the image segmentation ground truth data through the user input or the interaction information for the given image, and the artificial intelligence may be improved, and then the model may be stored in a server. In an embodiment, the model for automatically generating the image segmentation ground truth data through the user input or the interaction information for the given image, and the artificial intelligence may be loaded from the server to a client.

An embodiment discloses an apparatus and a system for automatically generating image segmentation ground truth data through artificial intelligence that has learned with an image similar to a given image, and segmentation ground truth of the image. In an embodiment, image segmentation ground truth data of a given semiconductor device TEM image may be automatically generated. In an embodiment, a boundary between materials may be automatically distinguished from the ground truth of the given semiconductor device TEM image.

An embodiment discloses an apparatus and a system for measuring a device core structure from a semiconductor device TEM image in which a boundary between materials is distinguished. In an embodiment, the device core structure may be automatically measured from the semiconductor device TEM image in which a boundary between materials is distinguished.

An embodiment discloses an apparatus and a system for storing a result of automatically measuring a device core structure (height, width, or roughness) from a semiconductor device TEM image in which a boundary between materials is distinguished. In an embodiment, the device core structure measured from the semiconductor device TEM image in which a boundary between materials is distinguished may be automatically stored.

In general, a facility for producing a TEM image may provide an image capture function for analysis, but may not provide a previous stage (sample production) function and a subsequent stage (device core structure automatic measurement) function, and may provide only an image analysis function after capturing an image. Measurement of a device core structure has been dependent on a manual work of a semiconductor manufacturing engineer due to technical difficulties in automatic TEM measurement. A TEM facility of an embodiment and an apparatus for processing the same enable automatic generation and automatic measurement for generation of ground truth and measurement of a device core structure, which used to depend on a manual work of a manufacturing engineer, only with minimal user input. A key portion of an embodiment may automatically generate ground truth through user input, to check a type of user input or an inference result image through a user interface in a client device. According to an embodiment, a user input and ground truth automatic generation model learning process may be repeated.

An embodiment may automatically generate ground truth using minimum user input and artificial intelligence, to improve efficiency and accuracy for segmentation learning. As compared to an existing manual generation method, it is possible to reduce a time period to generate ground truth and costs of user input. In addition, the automatic generation of ground truth may generate precise results without deviation between users, as compared to a manual generation method. An embodiment may contribute to complete automation of segmentation and measurement.

According to an embodiment, a segmentation learning technology for automatic measurement of a core structure of a semiconductor device is currently being developed by another facility, but source technology automatically generating ground truth for TEM image segmentation with minimal user input may be the world's first. An embodiment may be applicable not only to a TEM facility, but also to a scanning electron microscope (SEM) and a 3D analysis facility.

A TEM image processing apparatus, a facility system having the same, and an operation method thereof, according to an embodiment, may automatically generate a label for a semiconductor device using artificial intelligence automatically measuring a structure of the semiconductor device, or may learn a segmentation task, to reduce user's burden or to improve efficiency and accuracy.

A TEM image processing apparatus, a facility system having the same, and an operation method thereof, according to an embodiment, may automatically generate ground truth using minimum user input (or weak labeling) and artificial intelligence, to improve efficiency and accuracy for segmentation learning.

A TEM image processing apparatus, a facility system having the same, and an operation method thereof, according to an embodiment, may reduce a time period required to generate ground truth and costs for user input, as compared to an existing manual generation method.

In addition, a TEM image processing apparatus, a facility system having the same, and an operation method thereof, according to an embodiment, may generate an accurate result without variation between users due to automatic generation of ground truth, as compared to a manual generation method.

A TEM image processing apparatus, a facility system having the same, and an operation method thereof, according to an embodiment, may contribute to complete automation of segmentation and measurement.

While example embodiments have been illustrated and described above, it will be apparent to those skilled in the art that modifications and variations could be made without departing from the scope of the present inventive concept as defined by the appended claims.

1. A method of operating a transmission electron microscope (TEM) image processing apparatus, the method comprising:
acquiring a TEM image from a TEM facility;
performing weak labeling of the TEM image to produce a partially labeled TEM image;
generating ground truth for the partially labeled TEM image using a guide model;
performing image segmentation using training data consisting of a pair of the TEM image and the ground truth;
measuring a device core structure in the TEM image according to a result of the segmentation; and
displaying a measurement result according to the device core structure, and storing the measurement result in a database.

2. The method of claim 1, wherein the performing weak labeling comprises inputting one or several of a line, a connected line, a freedraw, a boundary, or a polygon to different regions of the TEM image, respectively.

3. The method of claim 1, wherein the guide model learns user input to generate segmentation ground truth.

4. The method of claim 1, wherein the generating ground truth comprises preparing a pre-learned guide model,
wherein the pre-learned guide model is one of a first guide model learned with a natural image, a second guide model learned with an image having a structure different from the device core structure, and a third guide model learned with the device core structure.

5. The method of claim 1, wherein the generating ground truth comprises:
outputting the ground truth for the TEM image using the guide model;
outputting the ground truth and an uncertainty map configured to be overlaid translucently on the TEM image;
determining whether updating of the guide model is required;
adding user input when the updating of the guide model is required; and
updating the guide model using the added user input,
wherein, in the updating the guide model, repetitive learning is performed so as not to overfit a current TEM image, and a weighted cross-entropy loss function is used for learning the guide model.

6. The method of claim 5, wherein the generating ground truth further comprises performing inference on the TEM image using the guide model to obtain the ground truth when updating of the guide model is not required.

7. The method of claim 1, wherein the TEM image and the ground truth are stored in the database as the training data.

8. The method of claim 1, wherein the performing image segmentation comprises learning and inferring the TEM image and the ground truth using a segmentation model.

9. The method of claim 1, wherein the measuring a device core structure comprises measuring the device core structure with respect to the TEM image of a semiconductor device in which a boundary between materials is distinguished.

10. The method of claim 1, wherein the measured device core structure comprises measurement result values for width, height, and roughness.

11. A method of operating a transmission electron microscope (TEM) image processing apparatus, the method comprising:
receiving a TEM image;
adding user input to the TEM image using weak labeling to produce a partially labeled TEM image;
generating ground truth for the partially labeled TEM image using a guide model;
determining whether the guide model satisfies a performance criterion; and
generating training data when the guide model satisfies the performance criterion,
wherein the ground truth includes an image for distinguishing a boundary between materials.

12. The method of claim 11, wherein the adding user input comprises inputting a point, a line, or a curve into one or more regions of the TEM image.

13. The method of claim 11, wherein the user input is at least one input of a line, a connected line, a freedraw, a boundary, or a polygon.

14. The method of claim 11, wherein the guide model is updated using active learning that adds user input based on an inference result and an uncertainty map.

15. The method of claim 14, further comprising storing the training data and the updated guide model in a database.

16. A method of operating a transmission electron microscope (TEM) image processing apparatus, the method comprising:
collecting training data consisting of a pair of a TEM image and ground truth corresponding to the TEM image;
learning a segmentation model for distinguishing a boundary between materials in an image;
determining whether the segmentation model satisfies a performance criterion;
performing inference for the TEM image using the segmentation model, when the segmentation model satisfies the performance criterion;
measuring a device core structure according to a result of the inference; and
outputting the device core structure.

17. The method of claim 16, wherein the training data is generated by weak labeling.

18. The method of claim 16, wherein the learning a segmentation model is repeated until the segmentation model satisfies the performance criterion.

19. The method of claim 16, wherein the learning a segmentation model comprises:
encoding user input or interaction information for the TEM image in a client device;
decoding the encoded user input or the encoded interaction information in a server device; and
updating a segmentation model using the decoded user input or the decoded interaction information in the server device,
wherein inference for the TEM image is performed using the updated segmentation model.

20. The method of claim 16, wherein the device core structure comprises a measurement value for a width, a measurement value for a height, and a measurement value for a roughness, and
wherein the method further comprises storing the measurement values for the width, the height, and the roughness in a database.

21.-30. (canceled)
